(19) United States
(12) Patent Application Publication
(10) Pub. No.: US 2023/0099143 A1
(43) Pub. Date: Mar. 30, 2023

(54) SHORT RANGE INFRARED IMAGING SYSTEMS

(71) Applicant: NATIONAL RESEARCH COUNCIL OF CANADA, Ottawa (CA)

(72) Inventors: Alexandre W. Walker, Ottawa (CA); Philip Waldron, Ottawa (CA)

(21) Appl. No.: 17/910,258

(22) PCT Filed: Mar. 19, 2021
(86) PCT No.: PCT/IB2021/052335

§ 371 Date: Sep. 8, 2022

Related U.S. Application Data
(60) Provisional application No. 63/002,608, filed on Mar. 31, 2020.

(51) Int. Cl. H01L 27/146; H04N 25/20

(52) U.S. Cl. CPC H01L 27/1461; H01L 27/14649; H04N 25/20

(57) ABSTRACT

An example short-wave infrared imaging device includes: a detector to detect light representing an object to be imaged, the detector comprising a semiconductor wafer divided into an array of detector cells; and an image processor coupled to the detector to generate image data based on the reflected light detected at the detector; and wherein each detector cell comprises: a detection region of the semiconductor wafer; a dopant doped into the wafer in a sub-cell pattern having at least two spaced apart doped regions, the dopant to generate a signal based on light received in the detection region of the detector cell; a metal contact joining the at least two doped regions; and a signal processing circuit coupled to the metal contact to transmit the signal to the image processor.

### FIELD

The specification relates generally to imaging systems, and more particularly to short-wave infrared imaging systems.

### BACKGROUND

Imaging devices may use semiconductor-based detectors to detect incoming light for imaging. The detectors include a dopant diffused into a semiconductor wafer. The area and perimeter of the junction between the dopant and the semiconductor wafer contribute to dark current experienced by the detector.

### SUMMARY

According to an aspect of the present specification, an imaging device is provided. The imaging device includes: a detector to detect light representing an object to be imaged, the detector comprising a semiconductor wafer divided into an array of detector cells; and an image processor coupled to the detector to generate image data based on the light detected at the detector. In particular, each detector cell of the detector comprises: a detection region of the semiconductor wafer; a dopant doped into the wafer in a sub-cell pattern having at least two spaced apart doped regions, the dopant to generate a signal based on light received in the detection region of the detector cell; a metal contact joining the at least two doped regions; and a signal processing circuit coupled to the metal contact to transmit the signal to the image processor.

According to another aspect of the present specification, another imaging device is provided. The imaging device includes: a detector to detect light representing an object to be imaged, the detector comprising a semiconductor wafer divided into an array of detector cells; and an image processor coupled to the detector array to generate image data based on the light detected at the detector. Each detector cell of the detector includes: a detection region of the semiconductor wafer; a signal generation sub-region of the detection region, the signal generation sub-region to generate a signal based on light received in the detection region of the detector cell, wherein the signal is generated at doped regions of the signal generation sub-region, and wherein the doped regions form a sub-cell pattern within the signal generation sub-region; a metal contact connected to the doped regions; and a signal processing circuit coupled to the metal contact to transmit the signal received at the detector cell to the image processor.

According to another aspect of the present specification, a method in an imaging device, of imaging an object is provided. The method includes: detecting, at a detector of the imaging device, light representing the object; for each detector cell of a plurality of detector cells of the detector: generating, at at least one of a plurality of doped regions of the detector cell, a signal representing light incident on the detector cell; wherein signals generated by any of the plurality of doped regions of the detector cell contribute to the signal representing light incident on the detector cell; and generating, based on the signals generated at each of the plurality of detector cells, image data representing the object.

### BRIEF DESCRIPTION OF DRAWINGS

Implementations are described with reference to the following figures, in which:

FIG. 1 depicts an example imaging system in accordance with the present specification;

FIG. 2A is a block diagram of an imaging device in the system of FIG. 1;

FIG. 2B is a schematic diagram of a detector of the imaging device of FIG. 2A;

FIG. 3 is a schematic diagram of a detector cell in the detector of FIG. 2B;

FIGS. 4A-4C are a schematic diagrams of different example detector cells for use imaging devices in accordance with the present specification; and

FIG. 5 is a flowchart of a method of imaging an object in the system of FIG. 1.

### DETAILED DESCRIPTION

Imaging devices, and in particular, short-wave infrared imaging devices, include detectors having an array of detector cells. Each detector cell includes a dopant diffused into a semiconductor wafer; the doped region of each cell is the region in which a signal representing light received at that detector cell is generated. A larger doped region increases the likelihood that a minority carrier excited by light received in the detector cell will be converted to a signal. However, the area and perimeter of the junction between the doped region and the semiconductor wafer is directly affects the dark current noise effects experienced by the detector. In particular, the area and perimeter of the junction contribute separately to the dark current effects. In some examples, the contribution from the perimeter may be the biggest effect on dark current, while in other examples, the contribution from the area may be the biggest effect on dark current. The contribution of the area and/or perimeter may vary, for example based on the semiconductor material and the dopant used.

According to an example of the present specification, a detector cell may have doped regions forming a sub-cell pattern to reduce the area or perimeter of the junction between the dopant and the semiconductor wafer. The dark current is thus also proportionally reduced. To compensate for the reduced area at which a signal may be generated, the semiconductor material used to form the wafer may be selected to have a high (e.g., in the range of about 10 μm to about 140 μm for an indium phosphide semiconductor material, or otherwise selected based on the structure of the detector, including the pitch of adjacent detector cells) minority carrier diffusion length to allow a minority carrier to be diffused, on average, across a longer path to reach one of the doped regions. As will be appreciated, other semiconductor materials may be selected to have different minority carrier diffusion lengths according to the desired properties of the detector cell. Thus, the detector cells may experience less dark current and the resulting image produced by an imaging device employing such detector cells has less noise.

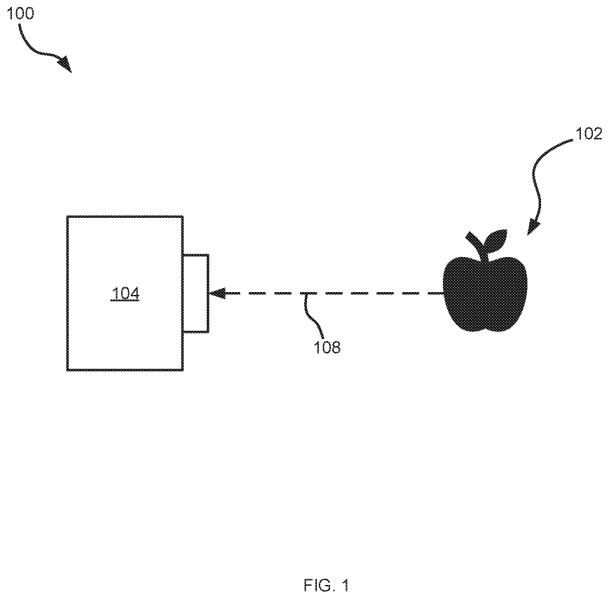

FIG. 1 depicts an example imaging system 100 for imaging an object 102 according to the present specification. The imaging system 100 includes an imaging device 104 (also referred to herein as simply device 104). In particular, the imaging device 104 may be a short-wave infrared imaging device. The device 104 is oriented towards the object 102 that it is imaging. Light 108 is reflected and/or emitted from the object 102. The light 108 is received by the device 104 and processed to generate image data representing the object 102. In particular, the device 104 may be configured to detect infrared light. In some examples, the device 104 may be coupled to another computing device (not shown), such as a server, a mobile device, a laptop, or the like, to receive information pertaining to the imaging operation, to transmit the image data from the imaging operation or to exchange other relevant communications.

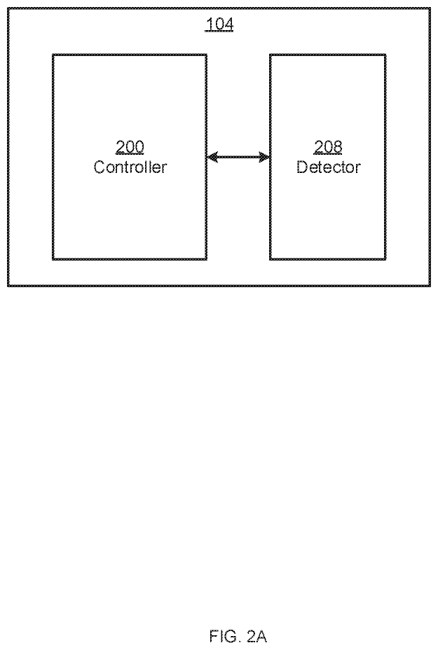

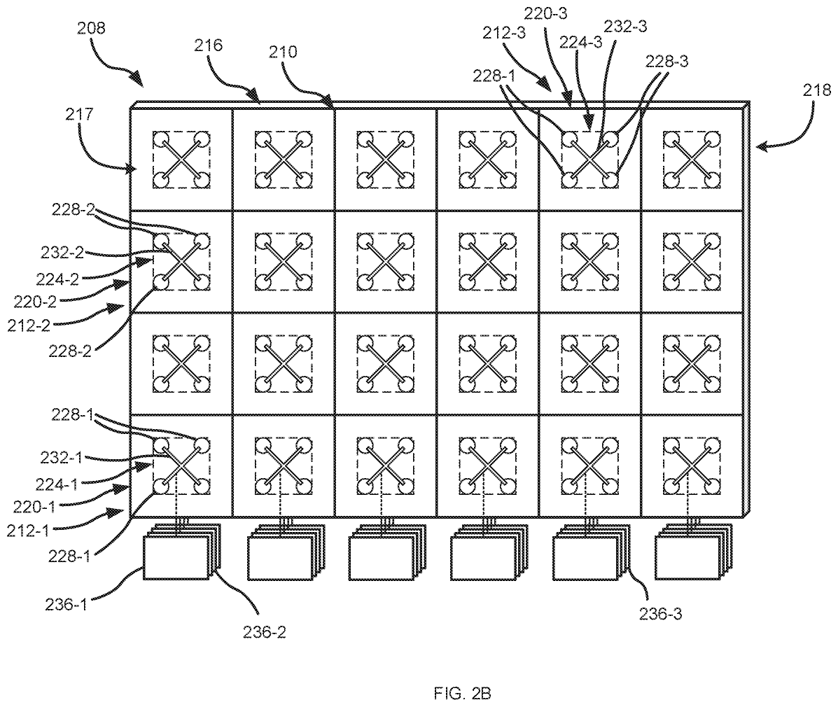

FIG. 2A is a block diagram depicting certain internal components of the device 104. Specifically, the device 104 includes a controller 200 and a detector 208.

The controller 200 may include a central processing unit (CPU), a microcontroller, a microprocessor, a processing core, a field-programmable gate array (FPGA) or similar. The controller 200 may include multiple cooperating processors. The controller 200 may cooperate with a memory to execute instructions to realize the functionality discussed herein. In particular, the memory may store applications including a plurality of computer-readable instructions executable by the controller 200. All or some of the memory may be integrated with the controller 200. The controller 200 and the memory may be comprised of one or more integrated circuits. In particular, the controller 200 is to generate image data based on signals received at the detector 208.

In some examples, the device 104 may further include a communications interface (not shown) interconnected with the controller 200. The communications interface includes suitable hardware (e.g. transmitters, receivers, network interface controllers and the like) allowing the device 104 to communicate with other computing devices. The specific components of the communications interface are selected based on the type of network or other links that the device 104 communicates over. The device 104 can be configured, for example, to communicate with a server via one or more links (e.g. wireless links including one or more wide-area networks such as the Internet, mobile networks, and the like, or wired links) to send and receive image data or other information pertaining to imaging operations of the device 104.

The device 104 may further include one or more input/output devices. For example, the device 104 may include a trigger button, switch or touch screen to receive input from an operator to initiate imaging operations. The device 104 may further include a display screen to display the image obtained during the imaging operation. In other examples, the device 104 may receive control signals (e.g., triggering initiation of an imaging operation) and transmit image data to and from another computing device via the communications interface.

In some examples, the device 104 further includes an emitter (not shown) interconnected with the controller 200. The controller 200 may be configured to control the emitter to emit light in a direction towards the object 102 toward which the device 104 is oriented for an imaging operation. More particularly, the emitter may be configured to emit short-wave infrared light (i.e., light having wavelengths of from about 1.4 μm to about 3 μm). In other examples, the device 104 may not include an emitter, and may simply detect infrared light in a transmission mode or to passively collect infrared radiation at the detector 208.

The device 104 further includes the detector 208 interconnected with the controller 200. The detector 208 is a photodetector and generally is configured to detect light. In some examples, the detector 208 may be selected for sensitivity to a specific wavelength of light (e.g., short-wave infrared light). For example, the detector 208 may be a semiconductor-based detector. That is, the detector 208 may include a semiconductor material with a dopant doped into the semiconductor material. In some examples, the dopant may be doped into the semiconductor material by masking the semiconductor material and patterning holes in a predetermined configuration, as will be described further herein, and diffusing the dopant material into the semiconductor. In other examples, the semiconductor material may be doped with the dopant material using ion implantation.

The semiconductor may be a suitable n-type semiconductor material, such as, but not limited to, indium phosphide, indium gallium arsenide phosphide, gallium antimonide, silicon, or the like. The dopant may be zinc, or a suitable p-type semiconductor material.

For example, referring to FIG. 2B, the detector 208 may be defined by a semiconductor wafer 216. As noted above, the semiconductor wafer 216 may be a suitable n-type semiconductor material, such as, but not limited to, indium phosphide, indium gallium arsenide phosphide, gallium antimonide, silicon, or the like. In particular, detector 208 may also include one or more detection layers, composed, for example, of indium gallium arsenic. The detection layers may be sandwiched between semiconductor wafer layers (e.g., a detection layer of indium gallium arsenide sandwiched between indium phosphide semiconductor wafer layers). The detector 208 may also include additional layers, such as one or more layers serving as electric field confinement layers (e.g., a charge sheet), and compositional gradient layers to facilitate electrical charge transfer from the one or more detection layers to the doped regions. For example, the detector 208 may include compositional gradient layers (composed of indium gallium arsenic phosphide) between an indium gallium arsenide detection layer and an indium phosphide semiconductor wafer layer, as well as a charge sheet in the indium phosphide semiconductor wafer layer above the detection layer. The charge sheet may be intentionally doped indium phosphide using silicon normally with a target thickness.

The semiconductor wafer 216 has a front face 217 at which the dopant is diffused and a rear face 218 opposite the front face 217. The semiconductor wafer 216 is divided into an array 210 of detector cells 212-1, 212-2, 212-3, and so on (referred to collectively as detector cells 212 and generically as a detector cell 212), wherein each detector cell 212 detects light independently. That is, each detector cell 212 in the detector array 210 corresponds to one pixel in the resulting image data. In the present example, the array 210 is a rectangular array; in other examples, the detector 208 may include detector cells in other spatial configurations, such as a linear array, a hexagonal array, an irregular arrangement, or the like.

Each detector cell 212 of the array 210 includes a detection region 220 at the front face 217 of the semiconductor wafer. That is, the detector cell 212-1 has a detection region 220-1, the detector cell 212-2 has a detection region 220-2, the detector cell 212-3 has a detection region 220-3, and so on. The detection region 220 of a given detector cell 212 is the region in which detected light may contribute to the signal detected by the corresponding detector cell 212. That is, light received in the detection region 220 of a given detector cell 212 contributes to the resulting image data identified for the corresponding pixel of the given detector cell 212. The detection regions 220 are depicted in the present example as being non-overlapping square regions for simplicity. In other examples, the detection regions 220 may overlap or be non-regularly shaped. For example, light incident at a point near an edge of adjacent detector cells 212 may excite a minority carrier which travels, in a first instance, to a first of the adjacent detector cells 212, and in a second instance to a second of the adjacent detector cells. Accordingly, the detection regions 220 of each of the adjacent detector cells 212 may overlap. Such overlap may contribute to crosstalk effects in the detector 208.

Each detector cell 212 further includes a signal generation sub-region 224 within the detection region 220. The signal generation sub-regions 224 generally define the regions in which a signal is generated for the respective detector cell 212 based on light received in the detection region 220. More particularly, each signal generation sub-region 224 includes doped regions 228 at which light is received to generate the signal. That is, the detector cell 212-1 has a signal generation sub-region 224-1 within the detection region 220-1, and the signal generation sub-region 224-1 containing doped regions 228-1. Similarly, the detector cell 212-2 has a signal generation sub-region 224-2 containing doped regions 228-2, the detector cell 212-3 has a signal generation sub-region 224-3 containing doped regions 228-3, and so on.

The doped regions 228 include a dopant doped into the semiconductor wafer 216. In some examples, the doped regions 228 may be diffused into the semiconductor wafer 216 and may reach the one or more detection layers. For example, the dopant may be zinc, cadmium, magnesium, or another suitable p-type material. The doped regions 228 of a given signal generation sub-region 224 form a sub-cell pattern within the signal generation sub-region 224. The detector cells 212 may include one doped region 228 forming the sub-cell pattern or more than one doped region 228 forming the sub-cell pattern, as will be described further herein. The sub-cell pattern generally has a smaller area than the signal generation sub-region 224. Accordingly, rather than a single aperture per detector cell 212 in which the dopant is diffused, the semiconductor wafer may include multiple aperture per detector cell 212. Specifically, the apertures may form the sub-cell pattern, and hence when the dopant is diffused into the apertures, the doped regions 228 also form the sub-cell pattern of the detector cell 212.

The sub-cell pattern formed by the doped regions 228 within the signal generation sub-region 224 reduces at least one of the area or perimeter of the junction between the dopant and the semiconductor wafer 216, relative to a doped region formed over the entirety of the signal generation sub-region 224. As dark current is proportional to the area and perimeter of the junction between the dopant and the semiconductor, detector cells including doped regions forming a sub-cell pattern experience a reduced dark current.

To compensate for the reduced area of the doped region 228 at which a signal may be generated, the semiconductor wafer 216 has a sufficiently long minority carrier diffusion length to increase the likelihood that a minority carrier will be received at one of the doped regions 228. The geometry of the sub-cell pattern and/or the quality of the semiconductor wafer (i.e., the minority carrier diffusion length) may be specifically selected so that on average, the semiconductor wafer 216 may diffuse the minority carrier over a sufficiently long path that the minority carrier reaches a doped region 228 prior to recombining. For example, the minority carrier diffusion length may be greater than half of a pitch between respective signal generation sub-regions 224 of adjacent detector cells 212. Specifically, for an indium phosphide semiconductor material, the minority carrier diffusion length may be in the range of about 10 μm to about 140 μm.

The detector 208 further includes metal contacts 232-1, 232-2, 232-3 and so on coupled to the respective doped regions 228. In particular, each detector cell 212 has a single metal contact 232 joining its doped regions 228. That is, the metal contact 232 for a given detector cell 212 joins each of the doped regions 228 for the given detector cell 212. For example, where the detector cell 212 includes two or more spaced apart doped regions 228, the metal contact 232 joins each of the two or more spaced apart doped regions 228. For example, the metal contact 232 may be a plate extending over at least a portion of each of the doped regions 228. The plate may thus cover a substantial portion of the detector cell 212. In such examples, the plate may act as a mirror to enhance absorption by the detector 208. In other examples, the metal contact 232 may be shaped to minimize coverage of the detector cell 212 while still joining the doped regions 228. For example, the metal contact 232 may include two or more arms extending towards each of the doped regions from a central point. The doped regions 228 are thus short-circuited together so that the doped regions 228 of the given detector cell 212 will generate or contribute to the same signal for that pixel. Sub-cell patterns including more than one doped region 228 therefore do not change the resolution of the detector 208, since the same signal will be generated at any of the doped regions 228 within the same detector cell 212.

The detector 208 further includes signal processing circuits 236-1, 236-2, 236-3, and so on, operatively coupled to the respective metal contacts 232. The signal processing circuit 236 for a given detector cell 212 is generally configured to process the signal received at the detector cell 212 and transmit it to the controller 200 for image processing. For example, the signal processing circuits 236 may form a single circuit, such as a read out integrated circuit (ROIC) which is operatively coupled to the metal contacts 232 at corresponding metal contacts of the ROIC. In some examples, the ROIC may be directly coupled at the front face 217 of the detector 208, for example, by having the corresponding metal contacts of the ROIC in physical contact with the metal contacts 232 of the detector 208. In such examples, the detector 208 may be configured to receive light at the back face 218. In other examples, the ROIC may be coupled to the detector 208 via wires or the like connecting the metal contacts 232 of the detector 208 to the corresponding metal contacts of the ROIC. In such examples, the detector 208 may be configured to receive light at the front face 217. The ROIC, in turn, is coupled to the controller 200 to transmit the signal detected at the controller.

In operation, light is received in the detection region 220 of a detector cell 212. The light excites an electron-hole pair which is diffused through the semiconductor wafer until it recombines or reaches a depletion region corresponding to a doped region 228 of a signal generation sub-region 224. Upon reaching the doped region 228, a signal is generated representing the light initially collected at the detection region 220. The signal is transmitted via the metal contact 232 and the signal processing circuit 236 to the controller 200 as the representative image data for the pixel corresponding to the detector cell 212. Since the doped regions 228 of a single detector cell 212 are joined by the same metal contact 232, the minority carrier may be received at any one of the doped regions 228 within the detector cell 212 and generate the same signal.

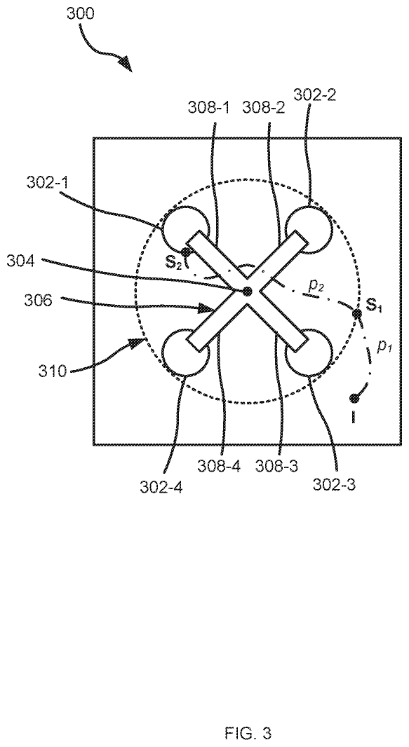

FIG. 3 depicts an example detector cell 300 defined by a detection region of a semiconductor wafer. The detector cell 300 includes a dopant diffused into the wafer in a sub-cell pattern having four spaced apart doped regions 302-1, 302-2, 302-3, and 302-4. The doped regions 302 are equidistant from a central point 304 and are approximately evenly spaced about a circle centered at the central point 304. The detector cell 300 further includes a metal contact 306 joining the doped regions 302. In the present example, the metal contact 306 includes arms 308-1, 308-2, 308-3, and 308-4 extending from the central point 304 to couple to the respective doped regions 302-1, 302-2, 302-3, and 302-4. Such a metal contact 306 may be utilized, for example, when the light is received at the front face 217 on the detector cell 300 to reduce reflections of light off the metal contact 306.

The doped regions 302 may define a signal generation sub-region 310 as the minimum circular region about the central point 304 which includes the doped regions 302. In prior art detector cells, the entirety of the signal generation sub-region 310 may be doped to allow for a large region in which a minority carrier may be received to generate a signal. However, such a large doped region creates a relatively large junction between the dopant and the semiconductor wafer, and a proportionally larger dark current effect experienced by the detector. In contrast, the present detector cell 300 has a relatively smaller junction between the dopant and the semiconductor wafer, and a proportionally smaller dark current effect experienced by the detector cell 300.

To reduce the junction between the dopant and the semiconductor wafer, the area of the sub-cell pattern of doped regions 302 is smaller than the area of the signal generation sub-region 310. Thus, the signal generation sub-region 310 also includes negative space (i.e., a portion of the signal generation sub-region 310 which is not doped) over which a minority carrier may travel prior to reaching a doped region 302. To compensate for the negative space in the signal generation sub-region 310, the semiconductor wafer may be selected to have a sufficiently long minority carrier diffusion length to improve carrier collection efficiency.

For example, light may be incident at a point I of the detector cell 300, exciting a minority carrier which travels along a path p₁ on the semiconductor wafer. At the point S₁, the minority carrier enters the signal generation sub-region 310 of the detector cell 300. In prior art systems, the minority carrier would generate a signal at the point S₁, having reached the doped region. In the present example, the minority carrier continues to be diffused through on the semiconductor wafer along a path p₂ within the signal generation sub-region 310. At the point S₂, the minority carrier reaches the doped region 302-1 and generates a signal representing the light incident at the point I. As will be apparent, in some examples, the path p₂ will be longer, while in other examples, the path p₂ will be shorter, including zero-length (e.g., when an edge of the doped region 302 is the same as an edge of the signal generation sub-region 310). Accordingly, the semiconductor wafer is selected to enable the minority carrier to be diffused through the semiconductor wafer for at least average length of paths p₂ within the signal generation sub-region 310 based on its minority carrier diffusion length.

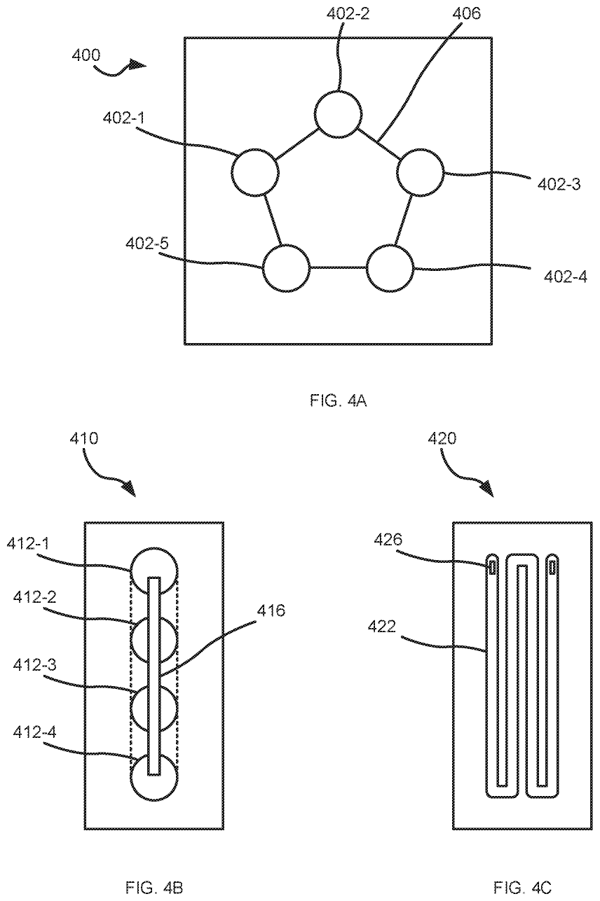

Referring now to FIGS. 4A-4C, various example sub-cell patterns for detector cells are depicted.

FIG. 4A depicts an example detector cell 400 defined by a detection region of a semiconductor wafer. The detector cell 400 includes a dopant diffused into the wafer in a sub-cell pattern having five spaced apart doped regions 402-1, 402-2, 402-3, 402-4, and 402-5. The doped regions 402 are equidistant from a central point and are approximately evenly spaced about a circle centered at the central point. The detector cell 400 further includes a metal contact 406 joining the doped regions 402. In the present example, the metal contact 406 is a metal plate in the shape of a pentagon, with each of the doped regions 402 located at a point of the pentagon. In other examples, the metal plate may be a square or a circle overlaying the entirety of each of the doped regions 402. Such a metal plate may be utilized, for example, when light is received at the rear face 218 on the detector cell 400. The shape of the metal contact 406 may be selected, for example, to allow for simpler manufacturing processes. The metal contact 406 thus short circuits the doped regions 402 together so that signals generated by any of the doped regions 402 correspond to the same pixel in the resulting image data.

In other examples, the sub-cell pattern may include three spaced apart doped regions, or more than five spaced apart doped regions. In further examples, the spaced apart doped regions may be arranged in a checkerboard or other spatial arrangement within the detection region. In still further examples, the spaced apart doped regions may have different sizes or shapes. The number, size, shape, and spatial arrangement of the doped regions may be selected, for example, to achieve a compromise between the area and perimeter of the junction between the dopant and the semiconductor and the predicted average path length (i.e., the minority carrier diffusion length) of a minority carrier to reach a doped region.

FIG. 4B depicts an example detector cell 410 defined by a detection region of a semiconductor wafer. In particular, the detector cell 410 may be utilized, for example in a 1-dimensional array, wherein prior art detector cells include a doped region extending substantially across the length of the detector cell 410, as depicted by the dashed region. In the present example, the detector cell 410 includes a dopant diffused into the wafer in a sub-cell pattern having four spaced apart doped regions 412-1, 412-2, 412-3, and 412-4. The doped regions 412 are arranged substantially linearly; that is the doped regions 412 form a line extending substantially across of the length of the detector cell 410. The detector cell 410 further includes a metal contact 416 joining the doped regions 412. In the present example, the metal contact 416 is a line extending from the first doped region 412-1, through the second and third doped regions 412-2 and 412-3 to the fourth doped region 412-4. The metal contact 416 thus short circuits the doped regions 412 together so that signals generated by any of the doped regions 412 correspond to the same pixel in the resulting image data. In other examples, other linearly extending patterns are contemplated to arrange the doped regions to mimic a tall pixel, for example, for a linear array of detector cells. Specifically, the doped regions may form a linearly extending pattern extending substantially across the length of the detector cell. The linear pattern may include two or more columns of doped regions (e.g., in a 2×10 array, a 3×8 array, etc.), a zig zag line, or another suitable arrangement in which the doped regions extend substantially across the length of the detector cell.

FIG. 4C depicts an example detector cell 420 defined by a detection region of a semiconductor wafer. The detector cell 420 has a dopant diffused into the wafer in a sub-cell pattern having a doped region 422 having a serpentine configuration. The serpentine configuration may be implemented in the detector cell 420 when area contributes relatively more to the dark current effect as compared to the perimeter. The detector cell 420 further includes metal contacts 426. In particular, the detector cell 420 includes two metal contacts 426 at the respective ends of the serpentine configuration to reduce the electrical resistance of the detector cell 420. In other examples, the detector cell 420 may have more than two metal contacts 426 to further reduce the resistance, or the detector cell 420 may have a single metal contact 426.

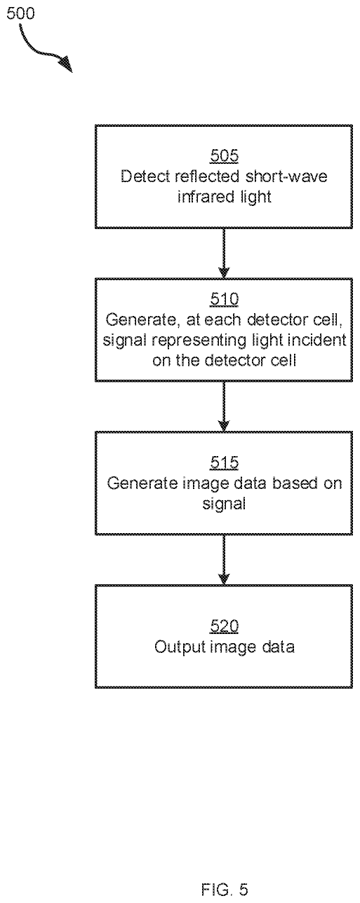

Referring now to FIG. 5, a flowchart depicting a method 500 of imaging an object is depicted. The method 500 will be described in conjunction with its performance in the system 100, and in particular at the device 104; in other examples the method 500 may be performed by other suitable systems.

The method 500 is initiated at block 505, for example, in response to an initiation signal. The initiation signal may be received, in some examples, at the device 104 from another computing device via a communications interface. In other examples, the initiation signal may be generated in response to user input at an input of the device 104, such as a trigger button, touch screen, or the like. In some examples, at block 505, in response to the initiation signal the controller 200 may initiate a pre-collection initiation process to prepare to process light received at the detector 208. At block 505, the device 104, and in particular, the detector 208 receives short-wave infrared light representing the object 102 and its surroundings. More specifically, light may be incident at various points on the detector cells 212 of the detector 208. In some implementations, prior to detecting the infrared light, the device 104 may emit, from an emitter, infrared light to be reflected from the object 102 and its surroundings.

At block 510, each detector cell 212 generates a signal representing the light received at the detector cell. Specifically, at least one of the doped regions 228 within the signal generation sub-region 224 of the detector cell 212 receives a minority carrier excited by the incident light and generates a signal representing the light incident on that particular detector cell 212. Since the doped regions 228 of a given detector cell 212 are joined by the metal contact 232, doped regions 228 of the same detector cell 212 contribute to the same signal for that detector cell 212.

At block 515, the controller 200 obtains the signals generated at each of the detector cells 212 at block 515 and generates image data representing the object to be imaged. More particularly, the controller 200 may obtain an association between each detector cell 212 in the array 210 with a pixel coordinate. The signal generated by the detector cell 212 may then be converted to an image data value (e.g., an RGB value or other suitable image data values) for the corresponding pixel in the image data.

Optionally, at block 520, the controller 200 may output the image data. For example, an image may be generated at a display screen of the device 104 based on the image data. In other examples, the device 104 may transmit the image data to another computing device via a communications interface.

As described above, an improved imaging device is provided. The detector cells of the imaging device have doped regions forming a sub-cell pattern to reduce the area and perimeter of the junction between the dopant and the semiconductor wafer. In particular, the reduction may be observed relative to prior art systems, in which the entire signal generation region may be doped to create a single, large doped region. The dark current experienced by the detector cell is also proportionally reduced relative to prior art systems. To compensate for the reduced area at which a signal may be generated, the semiconductor material used to form the wafer may be selected to have a high minority carrier diffusion length to allow an electron to be diffused, on average, across a longer path to reach one of the doped regions. Additionally, spaced apart doped regions within the same detector cell may be joined together by a metal contact to allow them to contribute to the same signal (i.e., the same pixel in the resulting image data) and maintain the resolution of the imaging device. The image data generated based on the presently described detector cells may thus include less noise, due to the reduced dark current experienced by each detector cell.

The scope of the claims should not be limited by the embodiments set forth in the above examples, but should be given the broadest interpretation consistent with the description as a whole.

1. An imaging device comprising:
a detector to detect light representing an object to be imaged, the detector comprising a semiconductor wafer divided into an array of detector cells; and
an image processor coupled to the detector to generate image data based on the light detected at the detector; and
wherein each detector cell comprises:
a detection region of the semiconductor wafer;
a dopant doped into the semiconductor wafer in a sub-cell pattern having at least two spaced apart doped regions, the dopant to generate a signal based on light received in the detection region of the detector cell;
a metal contact joining the at least two doped regions; and
a signal processing circuit coupled to the metal contact to transmit the signal to the image processor.

2. The imaging device of claim 1, wherein the semiconductor wafer comprises indium phosphide, and wherein the dopant comprises zinc.

3. The imaging device of claim 1, wherein a minority carrier diffusion length of the semiconductor wafer is in a range of about 10 μm to about 140 μm.

4. The imaging device of claim 1, wherein the at least two spaced apart doped regions are equidistant from a central point.

5. The imaging device of claim 1, wherein the at least two spaced apart doped regions form a linearly extending pattern extending substantially across a length of the detector cell.

6. A imaging device comprising:
a detector to detect light representing an object to be imaged, the detector comprising a semiconductor wafer divided into an array of detector cells; and
an image processor coupled to the detector to generate image data based on the light detected at the detector; and
wherein each detector cell comprises:
a detection region of the semiconductor wafer;
a signal generation sub-region of the detection region, the signal generation sub-region to generate a signal based on light received in the detection region of the detector cell, wherein the signal is generated at doped regions of the signal generation sub-region, and wherein the doped regions form a sub-cell pattern within the signal generation sub-region;
a metal contact connected to the doped regions; and
a signal processing circuit coupled to the metal contact to transmit the signal received at the detector cell to the image processor.

7. The imaging device of claim 6, wherein an area of the sub-cell pattern is less than an area of the signal generation sub-region.

8. The imaging device of claim 6, wherein the semiconductor wafer comprises indium phosphide, and wherein the doped regions comprise zinc diffused into the indium phosphide.

9. The imaging device of claim 6, wherein the detector further comprises one or more detection layers.

10. The imaging device of claim 9, wherein the detector further comprises one or more of: electric field confinement layers and compositional gradient layers to facilitate electrical charge transfer from the one or more detection layers to the doped regions.

11. The imaging device of claim 10, wherein the doped regions reach the one or more detection layers.

12. The imaging device of claim 6, wherein a minority carrier diffusion length of the semiconductor wafer is in a range of about 10 μm to about 140 μm.

13. The imaging device of claim 12, wherein the minority carrier diffusion length of the semiconductor wafer is about 80 μm.

14. The imaging device of claim 6, wherein a minority carrier diffusion length of the semiconductor wafer is greater than half of a pitch between respective signal generation sub-regions of adjacent detector cells.

15. The imaging device of claim 6, wherein the sub-cell pattern comprises at least two spaced apart doped regions equidistant from a central point.

16. The imaging device of claim 6, wherein the sub-cell pattern comprises at least two spaced apart doped regions forming a line.

17. The imaging device of claim 6, wherein the sub-cell pattern comprises a serpentine configuration.

18. A method, in an imaging device, of imaging an object, the method comprising:
detecting, at a detector of the imaging device, light representing the object;
for each detector cell of a plurality of detector cells of the detector:
generating, at at least one of a plurality of doped regions of the detector cell, a signal representing light incident on the detector cell;
wherein signals generated by any of the plurality of doped regions of the detector cell contribute to the signal representing light incident on the detector cell; and
generating, based on the signals generated at each of the plurality of detector cells, image data representing the object.

19. The method of claim 18, further comprising outputting the image data.
